(19) United States
(12) Patent Application Publication
(10) Pub. No.: US 2005/0212105 A1
(43) Pub. Date: Sep. 29, 2005

(54) Integrated circuit die and substrate coupling

(76) Inventor: Michael J. Walk, Mesa, AZ (US)

Correspondence Address: BUCKLEY, MASCHOFF, TALWALKAR LLC, 5 ELM STREET, NEW CANAAN, CT, 06840, US

(21) Appl. No.: 10/807,022

(22) Filed: Mar. 23, 2004

(51) Int. Cl. H01L 23/02

(52) U.S. Cl. 257/678

(57) ABSTRACT

A system may include a pre-formed portion of underfill material defining openings. The openings may be configured to pass electrical interconnects for coupling an integrated circuit die to a portion of a substrate.

### BACKGROUND

An integrated circuit (IC) die may include electrical devices that are integrated with a semiconductor substrate. The IC die may also include conductive paths that electrically couple the electrical devices to one another and to external connections. The die may include several layers of conductive paths, with each layer separated from adjacent layers by an inter-layer dielectric (ILD). The ILD may comprise material having an extremely low dielectric constant (k) in order to minimize capacitance coupling and crosstalk between the conductive paths.

Low-k ILD materials often exhibit a coefficient of thermal expansion (CTE) that differs significantly from other elements to which they are coupled, such as the other elements of the IC die and elements of an IC substrate to which the IC die is coupled. Moreover, low-k ILD materials are often brittle. These two characteristics may cause low-k ILD materials to crack during IC die and/or IC package fabrication.

### BRIEF DESCRIPTION OF THE DRAWINGS

FIG. 1 is a perspective view of two portions of underfill material according to some embodiments.

FIG. 2 is a bottom view of an IC die according to some embodiments.

FIG. 3 is a top view of an IC substrate according to some embodiments.

FIG. 4 is a cutaway side elevation of a system according to some embodiments.

FIG. 5 is diagram of a process according to some embodiments.

FIG. 6 is a side elevation of a portion of underfill material and a carrier according to some embodiments.

FIG. 7 is a side elevation of a portion of underfill material, a carrier, and a template according to some embodiments.

FIG. 8 is a cutaway side elevation of a portion of underfill material and a carrier according to some embodiments.

FIG. 9 is a cutaway side elevation of a portion of underfill material and an IC substrate according to some embodiments.

FIG. 10 is a diagram of a system according to some embodiments.

### DETAILED DESCRIPTION

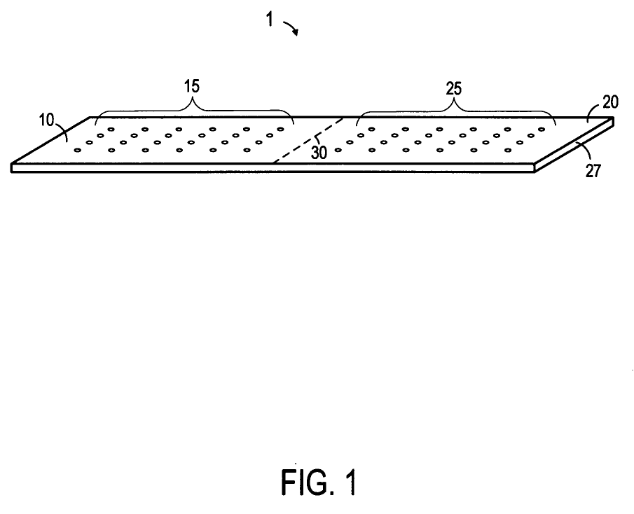

FIG. 1 is a perspective view of tape 1 according to some embodiments. Tape 1 comprises underfill material portion 10 and underfill material portion 20. Underfill material portions 10 and 20 may comprise no-flow underfill material. No-flow underfill material may comprise low-viscosity, thermally-polymerizable, liquid resin systems that may or may not include fluxing additives. Non-exhaustive examples include 50% by weight silica-filled underfill material and STAYCHIP™ DP-0115 by Cookson Electronics—Semiconductor Products. Underfill material portions 10 and 20 may be in a non-cured, partially-cured, and/or fully cured state.

Underfill material portion 10 defines openings 15. Openings 15 may be configured to pass electrical interconnects through underfill material portion 10. The electrical interconnects may in turn couple an IC die to an IC substrate. Such an arrangement might reduce ILD mechanical failures and/or provide high fabrication throughput.

An IC die may be located on one side of openings 15 and an IC substrate to which the IC die is coupled may be located on an opposite side of openings 15. With reference to FIG. 1, the IC die may be located “above” portion 10 and the IC substrate may be located “below” portion 10. An example of the above-described arrangement according to some embodiments is described below.

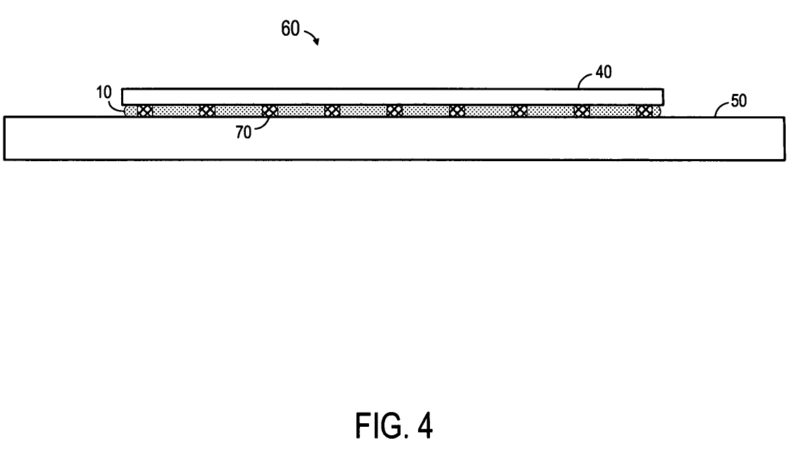

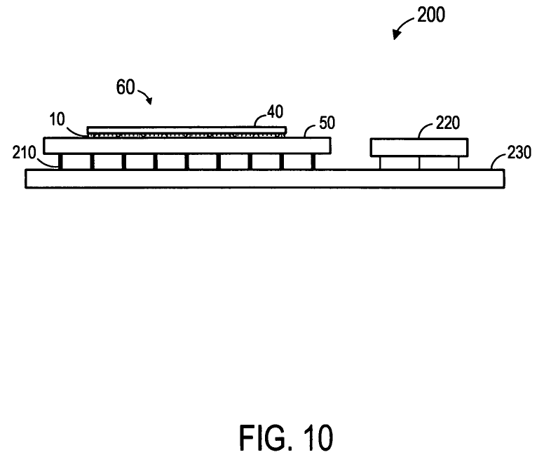

Underfill material portion 20 may define openings 25 that function similarly to openings 15 of underfill material portion 10. Openings 25 may therefore pass electrical interconnects through underfill material portion 20 for coupling an IC die to an IC substrate. The IC die and/or IC substrate may be identical to the IC die and/or IC substrate that is coupled by the electrical interconnects passed by openings 15. The embodiments described below and shown in FIGS. 4 and 10 include underfill material portion 10 disposed between a dedicated IC die and a dedicated portion of an IC substrate.

Underfill material portion 10 is coupled to underfill material portion 20 via coupling 30. Coupling 30 may comprise a physical connection that provides efficient separation of portion 10 from portion 20, or may simply comprise a solid region of material. According to some embodiments, a material located between portion 10 and portion 20 is different from the material of which portion 10 and portion 20 is composed.

In some embodiments, tape 1 includes additional underfill material portions coupled to underfill material portion 10 and/or to underfill material portion 20. For example, a portion of underfill material may be coupled to end 27 of portion 20 in the manner that portion 20 is coupled to portion 10. Accordingly, tape 1 may comprise a series of connected portions of underfill material that may be dispensed from a roll or other suitable dispensing system.

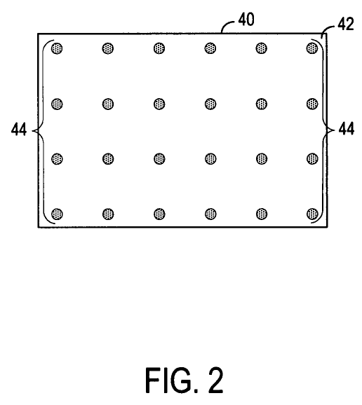

FIG. 2 illustrates IC die 40 according to some embodiments. IC die 40 includes integrated electrical devices and may be fabricated using any suitable substrate material and fabrication techniques. IC die 40 may provide one or more functions. In some embodiments, IC die 40 comprises a microprocessor chip having a silicon substrate.

Side 42 of IC die 40 includes electrical contacts 44. IC die 40 may comprise a flip chip arrangement in which electrical devices that are integrated therein reside between a substrate of IC die 40 and electrical contacts 44. In some embodiments, the substrate resides between the electrical devices and electrical contacts 44.

Electrical contacts 44 may comprise copper or lead-based contacts fabricated upon IC die 40. Electrical contacts 44 may comprise Controlled Collapse Chip Connect (C4) solder bumps. In this regard, conductive contacts 44 may be recessed under, flush with, or extending above first side 42 of IC die 40. Electrical contacts 44 may be electrically coupled to the electrical devices that are integrated into IC die 40.

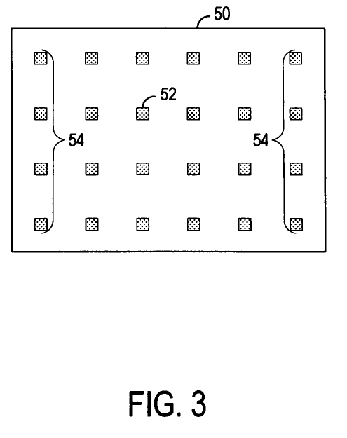

FIG. 3 is a view of a side of IC substrate 50 according to some embodiments. Substrate 50 may comprise any ceramic, organic, and/or other suitable material. Substrate 50 may be used to carry power and/or I/O signals between IC die 40 and external electrical components. Substrate 50 may also be used to transmit and receive signals directly to and from IC die 40 according to some embodiments.

First side 52 of substrate 50 includes electrical contacts 54. Electrical contacts 54 may comprise C4 solder bumps or plated copper contacts. Electrical contacts 54 may be recessed under, flush with, or extending above first side 52 of substrate. Although the embodiments of FIGS. 2 and 3 show electrical contacts 44 and 54 as having substantially square or circular cross section, respectively, in other embodiments one or more of electrical contacts 44 and 54 have cross sections of different and/or varying shapes.

FIG. 4 is a cutaway side elevation of system 60 according to some embodiments. System 60 includes underfill material portion 10, IC die 40 and IC substrate 50. System 60 also includes electrical interconnects 70, which pass through openings 15 of portion 10 and which couple electrical contacts 44 and electrical contacts 54. Underfill material portion 10 may encapsulate electrical interconnects 70 and may therefore protect electrical interconnects 70 from exposure to environmental hazards. Moreover, the CTE of IC die 40 may differ from the CTE of substrate 50 so as to cause undue stress on IC die 40 when system 60 is heated during the attachment of IC die 40 to substrate 50. Underfill material 10 may address this mismatch by absorbing some of the stress and/or distributing the stress away from IC die 40.

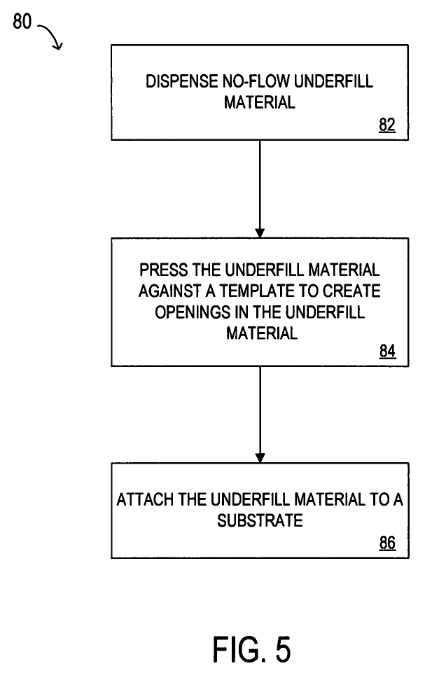

FIG. 5 is a diagram of process 80 according to some embodiments. Process 80 may be executed by one or more fabrication devices, and all or a part of process 80 may be executed manually. Process 80 may be executed at any time prior to fabrication of system 60.

Initially, no-flow underfill material is dispensed on a carrier at 82. No-flow underfill material may be dispensed according to any currently- or hereafter-known system, including a linear pump and a positive rotary displacement pump. The dispensed no-flow underfill material may be uncured, partially-cured or fully cured according to various embodiments. Partially- or fully-cured material may be dispensed in a laminate, sheet and/or tape form.

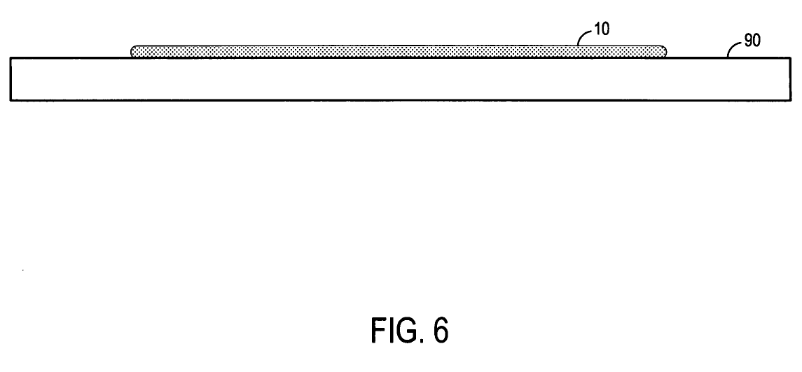

FIG. 6 is a side elevation of carrier 90 having underfill material portion 10 dispensed thereon according to some embodiments. Carrier 90 may comprise any surface on which no-flow underfill material may be dispensed. In some embodiments, underfill material portion 10 is dispensed as a bead and is flattened to the profile shown in FIG. 6 using a suitable tool. Underfill material 10 and/or carrier 90 may be precleaned using chemical and/or plasma-based techniques prior to 82.

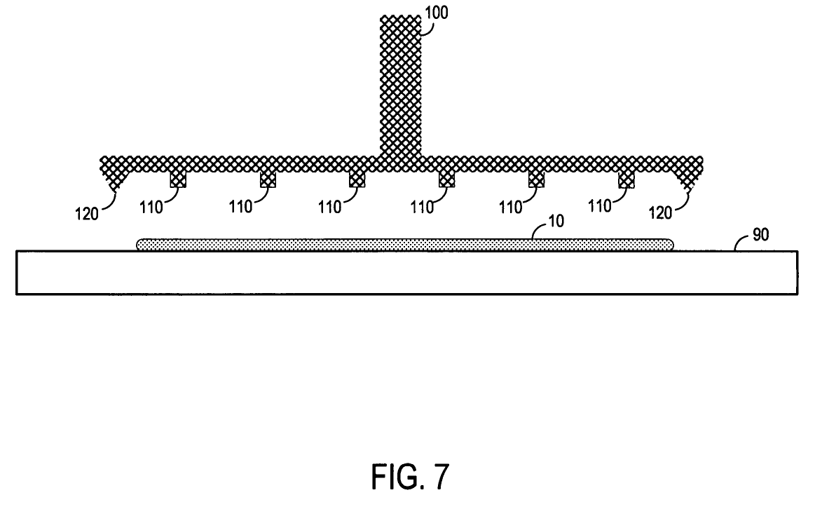

The underfill material is pressed against a template at 84 to create openings in the underfill material. FIG. 7 is a side cutaway view of template 100 approaching underfill material 10 in order to create openings according to some embodiments. Template 100 includes projections 110 to create the openings and lip 120 to establish the dimensions of underfill material 10 during 84. Carrier 90 may be moved toward template 100 and/or template 100 may be moved toward carrier 90 according to some embodiments of 84.

Projections 110 may be hollow so as to collect portions of underfill material 10 that are “punched-out” during 84. Underfill material 10 may be partially cured prior to 84 to enable clean removal of material from the areas in which openings are to be created. According to some embodiments, underfill material 10 is heated just prior to 84 to establish a desired degree of curing.

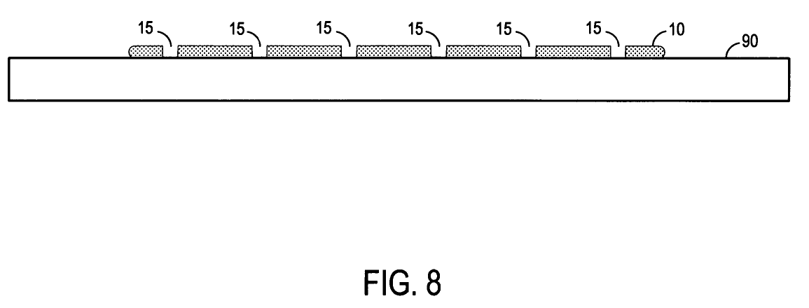

FIG. 8 is a cutaway side elevation of underfill material portion 10 and carrier 90 after 84. FIG. 8 shows openings 15 created by template 100. Openings 15 may be refined after 84 using etching techniques such as plasma etching.

The portion of underfill material is attached to an IC substrate at 86. The IC substrate may be precleaned prior to 86. According to some embodiments, the portion of underfill material is laminated onto the IC substrate. The portion of underfill material and the IC substrate may again be cleaned after 86.

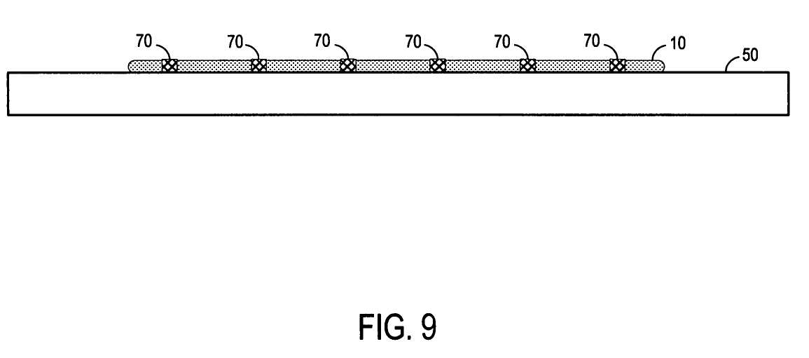

FIG. 9 is a cutaway side view of underfill material portion 10 and IC substrate 50 after 86 according to some embodiments. FIG. 9 shows electrical interconnects 70, which may be formed on substrate 50 before or after 86. Electrical interconnects 70 pass through respective ones of openings 15 and are used to couple IC substrate 50 to an IC die.

An IC die may be attached to the system of FIG. 9 after process 80. According to some embodiments, an IC die is placed thereon using a placement head of a pick-and-place machine. Such a machine may align electrical contacts of the IC die with respective ones of electrical interconnects 70 prior to placing the IC die. FIG. 4 illustrates one example of a resulting system.

Such a system may then be heated in order to form integral electrical connections between the IC die and the IC substrate, and/or to fully cure portion of underfill material 10. After curing, portion of underfill material 10 may form an inert protective polymer. Underfill material portion 10 may also include fluxing additives to deoxidize the metal surfaces of the electrical contacts of the IC die and of electrical interconnects 70. In some embodiments, flux is also or alternatively placed on the metal surfaces prior to heating.

FIG. 10 is a side elevation of system 200 according to some embodiments. System 200 may comprise components of a desktop computing platform. System 200 includes system 60 as described above, memory 220 and motherboard 230. System 60 of system 200 may comprise a microprocessor.

IC substrate 50 of system 60 may comprise multiple layers of conductive traces that are separated by layers of dielectric material and electrically coupled by vias formed within the dielectric material. Such traces and vias may electrically couple through-hole pins 210 to electrical contacts 54. Accordingly, pins 210 may carry signals such as power and I/O signals between IC die 40 and external devices. Pins 210 may be mounted directly on motherboard 230 or onto a socket (not shown) that is in turn mounted directly to motherboard 230. Motherboard 230 may comprise a memory bus (not shown) that is electrically coupled to pins 210 and to memory 220. Motherboard 230 may therefore electrically couple memory 220 to IC die 40. Memory 220 may comprise any type of memory for storing data, such as a Single Data Rate Random Access Memory, a Double Data Rate Random Access Memory, or a Programmable Read Only Memory.

The several embodiments described herein are solely for the purpose of illustration. The various features described herein need not all be used together, and any one or more of those features may be incorporated in a single embodiment. Some embodiments may include any currently or hereafter-known versions of the elements described herein. Therefore, persons skilled in the art will recognize from this description that other embodiments may be practiced with various modifications and alterations.

1. An apparatus comprising:
a pre-formed portion of underfill material defining openings, the openings to pass electrical interconnects for coupling an integrated circuit die to a portion of a substrate.

2. An apparatus according to claim 1, further comprising:
a second pre-formed portion of underfill material coupled to the portion of underfill material, the second portion of underfill material defining second openings, the second openings to pass second electrical interconnects for coupling a second integrated circuit die to a second portion of a substrate.

3. An apparatus according to claim 2, further comprising a pre-formed sheet of underfill material comprising the first portion and the second portion.

4. An apparatus according to claim 2, further comprising a pre-formed tape of underfill material comprising the first portion and the second portion.

5. An apparatus according to claim 1, further comprising:
the portion of the substrate.

6. An apparatus according to claim 5, further comprising:
the integrated circuit die.

7. An apparatus according to claim 1, further comprising:
the integrated circuit die.

8. An apparatus according to claim 1, the underfill material comprising:
no-flow underfill material.

9. A method comprising:
manufacturing a pre-formed portion of underfill material defining openings, the openings to pass electrical interconnects for coupling an integrated circuit die to a portion of a substrate.

10. A method according to claim 9, wherein manufacturing the portion comprises:
pressing the underfill material against a template of the openings to create the openings.

11. A method according to claim 10, wherein manufacturing the portion further comprises:
plasma etching the openings to further create the openings.

12. A method according to claim 9, further comprising:
attaching the underfill material to the substrate.

13. A method according to claim 12, further comprising:
coupling the substrate to the integrated circuit die using electrical interconnects passing through the openings.

14. A system comprising:
a microprocessor comprising:
an integrated circuit die;
a substrate; and
a pre-formed portion of underfill material pre-formed to define openings, the openings passing electrical interconnects for coupling the integrated circuit die to the substrate; and
a double data rate memory coupled to the microprocessor.

15. A system according to claim 14, the underfill material comprising:
no-flow underfill material.

16. A system according to claim 14,
the integrated circuit die comprising a first plurality of electrical contacts;
the substrate comprising a second plurality of electrical contacts; and
the electrical interconnects for coupling the first plurality of electrical contacts to the second plurality of electrical contacts.
